(19) United States
(12) Patent Application Publication
(10) Pub. No.: US 2026/0339400 A1
(43) Pub. Date: Oct. 29, 2026

(54) DISPLAY DEVICE BACK COVER HAVING CIRCUIT MOUNTING STRUCTURE

(71) Applicant: OHSUNG D&E CO., LTD., Busan (KR)

(72) Inventor: Sun Gyu KIM, Goyang-si (KR)

(21) Appl. No.: 19/356,238

(22) Filed: Oct. 13, 2025

(30) Foreign Application Priority Data
Apr. 23, 2025 (KR) 10-2025-0053234

(51) Int. Cl. G06F 1/183; H05K 7/14

(52) U.S. Cl. CPC G06F 1/183; H05K 7/1422

(57) ABSTRACT

Proposed is a display device back cover having a circuit mounting structure. The back cover includes a circuit board mounting portion having a groove in which a circuit board is mounted, and the circuit board mounting portion is integrally formed with either a single material panel or composite material panel during the process of forming the panel.

### CROSS REFERENCE TO RELATED APPLICATION

The present application claims priority to Korean Patent Application No. 10-2025-0053234, filed Apr. 23, 2025, the entire contents of which is incorporated herein for all purposes by this reference.

### BACKGROUND OF THE INVENTION

### Field of the Invention

The present disclosure relates generally to a display device back cover having a circuit mounting structure, the back cover being disposed on a back surface of a display panel to stably support various circuit boards or electrical components. More particularly, the present disclosure relates to a display device back cover having a circuit mounting structure that is integrally formed using a metal or composite material.

### Description of the Related Art

In display devices, electronic components such as circuit boards, power boards, or main boards require secure mounting within the device, and this is typically achieved through separate fixing members or chassis plates.

These fixing members or chassis plates that perform similar functions are generally manufactured separately from metal materials and are affixed to a back cover or internal chassis structure of the display device by means of screw fastening, riveting, or tab insertion.

Multiple fastening holes are formed on an upper surface of the fixing member, and a circuit board (e.g., PCB, power board, main board, etc.) is directly fastened to the fixing member using screws, bolts, or clips at positions corresponding to the fastening holes, providing mechanical support or securement for the board.

However, this configuration requires separate production of fixing members and their attachment to the back cover or internal structure, which increases part count, complicates assembly, and raises manufacturing costs. In particular, when the fixing members and the back cover are formed as different parts, it leads to difficulties in precisely controlling the tolerance between separate parts, and poses a risk of wear or damage to the fixing members from repeated installation and removal. Also, the need to remove burrs created during the fastening process and to ensure precise screw position alignment adds a burden for quality control.

In a conventional design, devices used separate parts for a back cover of an aluminum composite material (ACM) or a single metal material (e.g., aluminum panel, steel sheet, etc.) and a distinct fixing member or chassis plate for holding a circuit board, with the fixing member or chassis plate then being attached to the back cover. In this case, there is a requirement for additional processes like fastening between the back cover and the fixing member, forming screw holes for mounting the circuit board, and installing reinforcing ribs. This ultimately leads to problems of increased number of processes, increased number of molds, decreased productivity, and increased price per unit.

Additionally, while a back cover structure using a composite material offers advantages like reduced weight, thermal insulation, and rigidity, integrating circuit board mounting features is not a widely known technology. In particular, a process of integrating mounting features directly into a laminated structure of metal and resin or fiber is still underdeveloped. Current technologies predominantly rely on attaching separate mounting parts to the composite structure, rather than using a fully integrated approach.

In this regard, an emerging need is for a technology that integrates circuit board mounting features into the back cover itself, thereby reducing the number of parts, shortening the number of processes, and improving rigidity and assembly precision.

Accordingly, the present applicant has proposed the present disclosure to solve the above-mentioned problems, and as a document of related art, there is Korean Patent No. 10-2263379, entitled “Method for press molding of compound material”.

The foregoing is intended merely to aid in the understanding of the background of the present disclosure, and is not intended to mean that the present disclosure falls within the purview of the related art that is already known to those skilled in the art.

### SUMMARY OF THE INVENTION

Accordingly, the present disclosure has been made keeping in mind the above problems occurring in the related art, and one objective of the present disclosure is to provide a display device back cover having a circuit mounting structure in which a circuit board mounting portion for supporting a circuit board is integrally formed on one surface of the back cover, and the back cover is formed by a panel made of a composite material or single metal material to reduce the number of parts while ensuring rigidity and assembly precision.

In order to achieve the above objective, according to one aspect of the present disclosure, there is provided a display device back cover having a circuit mounting structure, the display device back cover including: a circuit board mounting portion having a groove in which a circuit board is mounted, wherein the circuit board mounting portion may be integrally formed with either a single material panel or composite material panel during the process of forming the panel.

Additionally, the groove may include multiple mounting grooves that are formed on one surface of the single material panel or composite material panel constituting the back cover.

Additionally, the multiple mounting grooves may be spaced apart from each other to correspond to an outer shape of the circuit board.

Additionally, the circuit board mounting portion may include a protruding rib that is formed protrudingly from the surface of the single material panel or composite material panel constituting the back cover and defines the multiple mounting grooves.

Additionally, the single material panel may be composed of a metal or an alloy of two or more different metals.

Additionally, the composite material panel may include: a first skin layer composed of a metal or an alloy of two or more different metals; a plastic resin layer laminated on the first skin layer; and a second skin layer laminated on the resin layer and composed of a metal or an alloy of two or more different metals.

Additionally, a fastening hole may be formed in the circuit board mounting portion to mount the circuit board in the multiple mounting grooves, and the fastening hole may be formed on the surface of the panel or the protruding rib that defines the multiple mounting grooves.

Additionally, the fastening hole may be threaded to form a thread on an inner surface thereof so as to enable screw fastening.

Additionally, when the fastening hole is formed in the composite material panel, the fastening hole may penetrate the first skin layer, the resin layer, and the second skin layer, and the thread may be formed in the second skin layer.

Additionally, the multiple mounting grooves and the protruding rib may be formed simultaneously by a single mold during the process of forming the single material panel or composite material panel constituting the back cover.

Additionally, the multiple mounting grooves may be arranged symmetrically left and right with respect to a longitudinal center line of the single material panel or composite material panel constituting the back cover.

Additionally, the resin layer may be composed of polypropylene (PP), polycarbonate (PC), or a fiber-reinforced resin, and the first skin layer or the second skin layer may be composed of a steel sheet (GI, SECC) or an aluminum alloy.

The display device back cover having the circuit mounting structure according to the present disclosure directly integrally forms the circuit board mounting portion during the process of forming the back cover, without requiring a separate fixing member or chassis plate for mounting a circuit board. This enables simultaneous realization of a reduced part count, simplified assembly, and a reduced number of molds.

Furthermore, the display device back cover having the circuit mounting structure according to the present disclosure precisely forms the multiple mounting grooves corresponding to the outer shape of the circuit board, along with the protruding rib defining the grooves, using a single mold. This ensures stable mounting of the circuit board without positional deviation or misalignment, while greatly enhancing assembly convenience for workers and productivity.

Additionally, the display device back cover having the circuit mounting structure according to the present disclosure forms the thread in the fastening hole that penetrates the first skin layer, the resin layer, and the second skin layer of the composite material panel. This ensures mechanical strength without wear even during repeated screw insertion and removal, which is advantageous for enhancing vibration resistance and long-term durability of the board.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a rear perspective view illustrating a display device back cover having a circuit mounting structure according to an embodiment of the present disclosure;

FIG. 2 is a rear view illustrating the display device back cover having the circuit mounting structure according to the embodiment of the present disclosure;

FIG. 3 is a front view illustrating the display device back cover having the circuit mounting structure according to the embodiment of the present disclosure;

FIG. 4 is a perspective view illustrating a state cut along line A-A' in FIG. 1; and

FIG. 5 is a sectional view enlargely illustrating area A in FIG. 4.

### DETAILED DESCRIPTION OF THE INVENTION

The advantages and features of the disclosure and ways to achieve them will be apparent by making reference to embodiments as described below in detail in conjunction with the accompanying drawings.

However, the disclosure is not limited to the embodiments set forth below, but may be implemented in various different forms. The following embodiments are provided only to completely disclose the disclosure and inform those skilled in the art of the scope of the disclosure, and the disclosure is defined only by the scope of the appended claims.

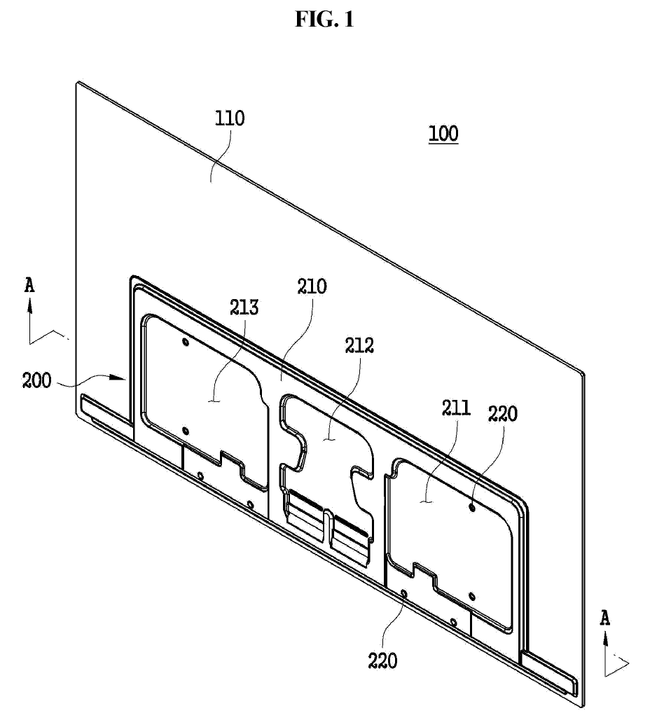

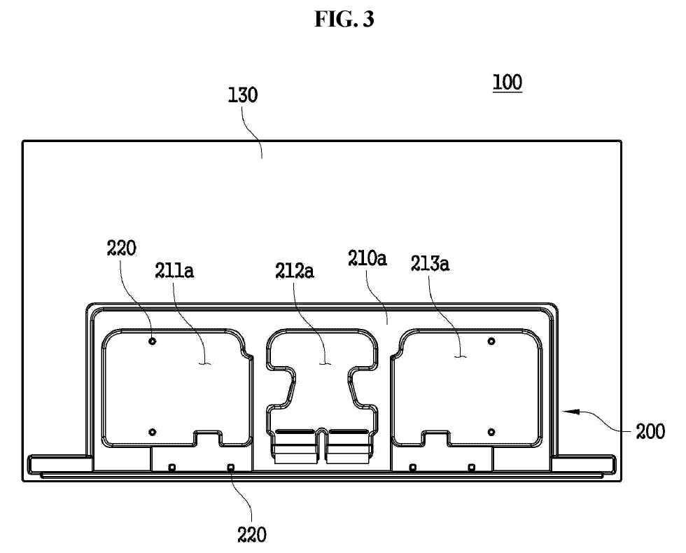

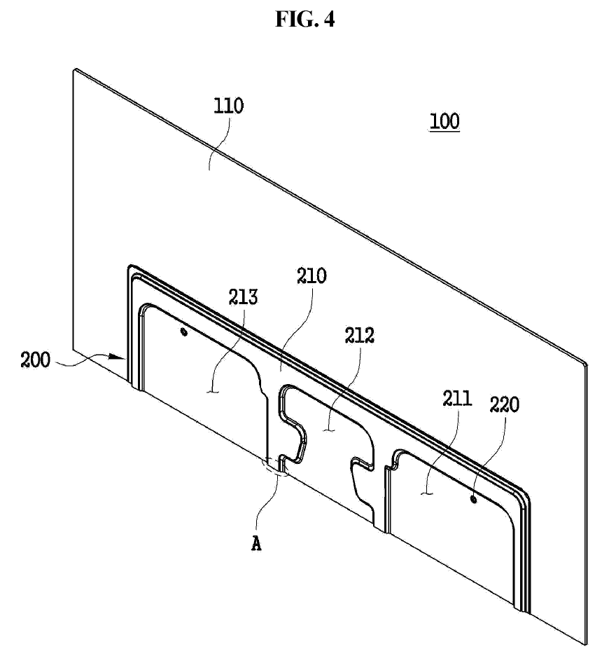

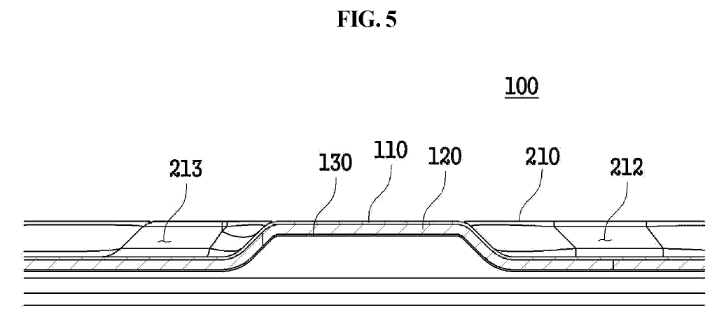

A display device back cover having a circuit mounting structure according to an embodiment of the present disclosure will now be described with reference to FIGS. 1-5. In the following description, detailed descriptions of known functions and components incorporated herein will be omitted when it may make the subject matter of the present disclosure unclear.

First, the present disclosure relates generally to a display device back cover with an integrally formed structure for mounting a circuit board such as a main board, a power board, a PCB, etc. More particularly, the present disclosure relates to a technology that eliminates the need for separately provided fixing members or chassis plates, and instead directly forming a structure that allows mounting of a circuit board on the back cover itself, thereby achieving effects such as a reduction in the number of parts, improved assembly efficiency, simplified manufacturing, and enhanced product rigidity.

In particular, the present disclosure is characterized in that a panel constituting the back cover may be made of either a single material or a composite material, a circuit board mounting portion is integrally formed during the process of forming the panel, and multiple grooves for mounting the circuit board are provided.

Hereinafter, a display device back cover 100 having a circuit mounting structure according to an embodiment of the present disclosure will be described in detail with reference to FIGS. 1-5.

The display device back cover 100 according to the embodiment of the present disclosure may be formed by a single material panel. In this case, the panel may be composed of a metal such as iron or aluminum, or an alloy of two or more different metals.

The single material panel has structural rigidity, and may be manufactured through a forming process such as press forming, in-mold forming, or hot pressing so that a circuit board mounting portion 200, which will be described later, is formed integrally therewith.

Additionally, the display device back cover 100 according to the embodiment of the present disclosure may be formed by a composite material panel.

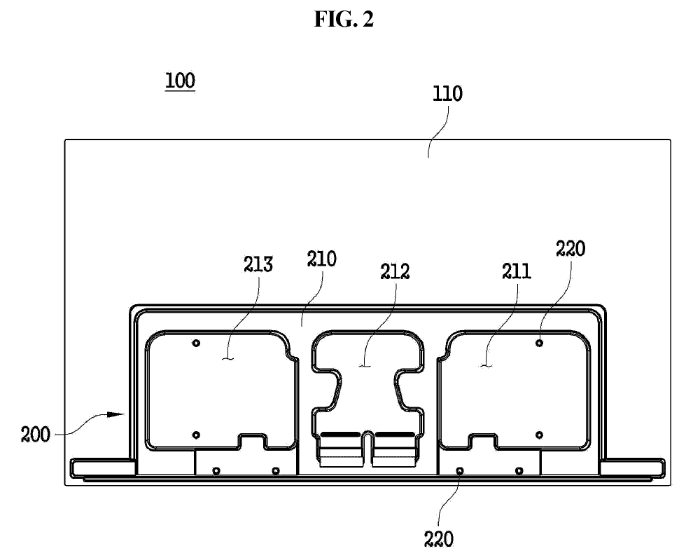

The composite material panel may have a multilayer structure formed by laminating and bonding different layers. As illustrated in FIGS. 2, 3, and 5, it may be configured as a three-layer structure including: a first skin layer 110 composed of a metal or alloy; a resin layer 120 composed of a thermoplastic resin or fiber-reinforced composite resin; and a second skin layer 130 composed of a metal or alloy.

The first skin layer 110, the resin layer 120, and the second skin layer 130 may sequentially laminated and bonded to each other. Here, the first skin layer 110 and the second skin layer 120 may be composed of a steel sheet (GI, SECC) or an aluminum alloy, and the resin layer 130 may be composed of a thermoplastic resin such as polypropylene (PP), polycarbonate (PC), PA66, or a composite resin in which fibers are incorporated into these resins. For reference, when fibers are incorporated into the resin layer 120, the mechanical strength and heat resistance of the resin layer are improved, and stable shape retention during forming is also achieved.

Such a configuration appropriately allocates material characteristics and functional roles to each layer, thereby simultaneously achieving multiple benefits, including enhanced rigidity of the entire panel, improved thermal insulation, and weight reduction. In particular, the metallic skin layer provides structural support for the entire circuit board mounting portion, while the resin layer offers molding flexibility and thermal insulation. This enables the realization of a lightweight structure.

Each layer of the composite material panel configured as described above may be integrated through thermo-compression or forming processes, thereby simultaneously forming the back cover 100 and the circuit board mounting portion 200, which will be described later, into a single, integrated body.

For reference, in the drawings according to the embodiment of the present disclosure, the back cover 100 is depicted as being a composite material panel.

As illustrated in FIGS. 1-5, the back cover 100 according to the embodiment of the present disclosure includes the circuit board mounting portion 200 having a groove in which a circuit board (not illustrated) is mounted.

The circuit board mounting portion 200 may be defined as being a component that is integrally formed with a single material panel or composite material panel constituting the back cover 100 during the process of forming the panel.

The circuit board mounting portion 200 in the embodiment of the present disclosure is a component integrally formed on one surface of the back cover 100, and may replace a separate support member such as a fixing member or chassis plate that was provided separately in the related art.

The circuit board mounting portion 200 may have a groove including multiple mounting grooves 211, 212, and 213 formed on one surface of the single material panel or composite material panel constituting the back cover 100.

The mounting grooves 211, 212, and 213 may be provided on the surface of the single material panel or composite material panel constituting the back cover 100, and may be formed integrally with the panel during the forming process.

As illustrated in FIGS. 1 and 2, the mounting grooves 211, 212, and 213 may be formed in a recessed shape having a predetermined depth on the surface of the panel.

In FIGS. 1 and 2, three mounting grooves 211, 212, and 213 are illustrated as being formed with a predetermined depth in the form of recesses on one surface of the first skin layer 110 constituting the composite material panel.

The mounting grooves 211, 212, and 213 may have a recessed shape corresponding to the outer shape of the circuit board, and allow the circuit board to be accurately and stably secured to the surface of the first skin layer 110.

The mounting grooves 211, 212, and 213 not only serve to provide a space for simply supporting the circuit board, but also perform a guiding function that prevents positional deviation or misalignment of the circuit board.

Additionally, the multiple mounting grooves 211, 212, and 213 are arranged spaced apart from each other, and the interval between the mounting grooves 211, 212, and 213 is designed according to the shape of the circuit board to be mounted and fixing points thereof.

As such, the configuration in which the mounting grooves 211, 212, and 213 are arranged in a spaced-apart manner allows the circuit board to be supported by multiple grooves at respective points rather than by a single large groove. This helps maintain uniform flatness and fixing strength across the entire circuit board, while effectively dispersing board movement caused by impact or vibration.

Additionally, the mounting grooves 211, 212, and 213 may be arranged symmetrically left and right with respect to a longitudinal center line of the single material panel or composite material panel constituting the back cover 100. This configuration in which the mounting grooves 211, 212, and 213 are left-right symmetrical with respect to the longitudinal center line is advantageous in that they are precisely positioned to match the outer shape of the circuit board, while also allowing the circuit board to be stably mounted in an aligned state on the back cover 100.

Additionally, the left-right symmetrical arrangement of the mounting grooves 211, 212, and 213 allows the mounting position of the circuit board to be intuitively recognized by workers, thereby enhancing assembly convenience for workers. From the perspective of mold design, applying a symmetrical mold structure is advantageous for ensuring precision in mold fabrication and maintaining structural balance. Furthermore, the left-right symmetrical structure of the mounting grooves 211, 212, and 213 can prevent movement or misalignment of the circuit board and contribute to enhanced durability against external forces.

Meanwhile, as illustrated in FIGS. 1, 2, and 5, the mounting grooves 211, 212, and 213 may be defined by a protruding rib 210 formed protrudingly from the surface of the first skin layer 110.

The protruding rib 210 may be implemented as a structure that protrudes from the surface of the single material panel or composite material panel constituting the back cover 100.

While the mounting grooves 211, 212, and 213 are depressed in a recessed shape, the protruding rib 210 protrudes outward from the surface of the panel, forming a partition wall that defines the three mounting grooves 211, 212, and 213.

The protruding rib 210 not only physically defines the layout boundary of the circuit board but also serves as a guide, when mounting the circuit board in the mounting grooves 211, 212, and 213, to assist in aligning the position of the circuit board within the mounting grooves 211, 212, and 213.

In addition to its role in defining the mounting grooves 211, 212, and 213, the protruding rib 210 also act as a mechanical resistance element that prevents horizontal shifting or positional deviation caused by vibration, which may occur when mounting the circuit board in the mounting grooves 211, 212, and 213.

Similar to the mounting grooves 211, 212, and 213, the protruding rib 210 may be formed integrally with the panel during the process of forming the back cover 100.

Additionally, the mounting grooves 211, 212, and 213 and the protruding rib 210 of the circuit board mounting portion 200 may be formed simultaneously by a single mold during the process of forming the single material panel or composite material panel constituting the back cover 100.

As such, the configuration in which the mounting grooves 211, 212, and 213 and the protruding rib 210 are integrally formed in the same forming process using a single mold allows the circuit board mounting structure to be integrated simultaneously with the forming of the back cover 100. This provides a structural foundation for precisely supporting the circuit board without requiring separate component assembly or insertion processes.

Moreover, simultaneously forming the mounting grooves 211, 212, and 213 and the protruding rib 210 can prevent positional misalignment errors between the two components, thereby enhancing the mounting precision of the circuit board. This configuration also provides process-related benefits, including a reduction in the number of molds, simplified manufacturing, shorter assembly time, and improved overall productivity.

Meanwhile, as illustrated in FIGS. 1-3, the circuit board mounting portion 200 in the embodiment of the present disclosure may have multiple fastening holes 220 for securing the circuit board to the mounting grooves 211, 212, and 213.

The fastening holes 220 may be formed on the surface of the panel or the protruding rib 210 that defines the multiple mounting grooves 211, 212, and 213, and are used to securely fix the circuit board using fastening means such as screws.

Each of the fastening holes 220 is threaded to form a thread on an inner surface thereof so as to enable screw fastening. When formed in the composite material panel, the fastening hole 220 may penetrate the first skin layer 110, the resin layer 120, and the second skin layer 130, with the thread being formed in the second skin layer 130. As such, forming threads in the metallic second skin layer 130 that defines the fastening holes 220 ensures strong fastening even under repeated screw insertion and removal.

With this configuration, the circuit board mounted in the mounting grooves 211, 212, and 213 can remain securely fixed within the mounting grooves 211, 212, and 213 through the fastening holes 220 without movement or deviation due to vibration or external forces.

Although a specific exemplary embodiment of the present disclosure has been shown and described, the present disclosure is not limited to the described exemplary embodiment.

Instead, it would be appreciated by those skilled in the art that changes may be made to the exemplary embodiment without departing from the principles and spirit of the disclosure, the scope of which is defined by the claims and their equivalents.

1. A display device back cover having a circuit mounting structure, the display device back cover comprising:
a circuit board mounting portion having a groove in which a circuit board is mounted,
wherein the circuit board mounting portion is integrally formed with either a single material panel or composite material panel during the process of forming the panel.

2. The display device back cover of claim 1, wherein the groove includes multiple mounting grooves that are formed on one surface of the single material panel or composite material panel constituting the back cover.

3. The display device back cover of claim 2, wherein the multiple mounting grooves are spaced apart from each other to correspond to an outer shape of the circuit board.

4. The display device back cover of claim 3, wherein the circuit board mounting portion includes a protruding rib that is formed protrudingly from the surface of the single material panel or composite material panel constituting the back cover and defines the multiple mounting grooves.

5. The display device back cover of claim 4, wherein the single material panel is composed of a metal or an alloy of two or more different metals.

6. The display device back cover of claim 4, wherein the composite material panel includes:
a first skin layer composed of a metal or an alloy of two or more different metals;
a plastic resin layer laminated on the first skin layer; and
a second skin layer laminated on the resin layer and composed of a metal or an alloy of two or more different metals.

7. The display device back cover of claim 5, wherein a fastening hole is formed in the circuit board mounting portion to mount the circuit board in the multiple mounting grooves, and
the fastening hole is formed on the surface of the panel or the protruding rib that defines the multiple mounting grooves.

8. The display device back cover of claim 7, wherein the fastening hole is threaded to form a thread on an inner surface thereof so as to enable screw fastening.

9. The display device back cover of claim 8, wherein when the fastening hole is formed in the composite material panel,
the fastening hole penetrates the first skin layer, the resin layer, and the second skin layer, and
the thread is formed in the second skin layer.

10. The display device back cover of claim 4, wherein the multiple mounting grooves and the protruding rib are formed simultaneously by a single mold during the process of forming the single material panel or composite material panel constituting the back cover.

11. The display device back cover of claim 2, wherein the multiple mounting grooves are arranged symmetrically left and right with respect to a longitudinal center line of the single material panel or composite material panel constituting the back cover.

12. The display device back cover of claim 6, wherein the resin layer is composed of polypropylene (PP), polycarbonate (PC), or a fiber-reinforced resin, and
the first skin layer or the second skin layer is composed of a steel sheet (GI, SECC) or an aluminum alloy.
